(19) United States
(12) Patent Application Publication
(10) Pub. No.: US 2019/0173005 A1
(43) Pub. Date: Jun. 6, 2019

(54) METHOD FOR FABRICATING AN OXRAM MEMORY LOCATION FOR LIMITING DISPERSIONS

(71) Applicant: Commissariat a I'energie atomique et aux energies alternatives, Paris (FR)

(72) Inventors: Marios Barlas, St Martin D'heres (FR); Philippe Blaise, Grenoble (FR); Laurent Grenouillet, Claix (FR); Boubacar Traore, Grenoble (FR)

(73) Assignee: Commissariat a I'energie atomique et aux energies alternatives, Paris (FR)

(21) Appl. No.: 16/210,331

(22) Filed: Dec. 5, 2018

(30) Foreign Application Priority Data
Dec. 5, 2017 (FR) 17 61627

(51) Int. Cl. H01L 45/00; H01L 27/24

(52) U.S. Cl. CPC H01L 45/08; H01L 45/1233; H01L 45/146; H01L 45/147; H01L 45/165; H01L 27/2463; H01L 45/1253

(57) ABSTRACT

A method for fabricating an OxRAM type memory location, including the steps of providing a stack including a superposition of a first layer that includes a first material made of Ti at more than 30% by mole fraction; a second layer made of HfO₂ positioned under the first layer; via an ion implantation of a second material chosen from Xe, Kr or Ar in the first layer, carrying out an implantation of the first material in the second layer by collision with recoil effect in the first layer.

The invention relates to RRAM memories, and in particular the methods for fabricating such memories.

In order to overcome the limits in terms of miniaturization, power consumption and complexity of fabricating floating-gate non-volatile memory technologies, the semiconductor industry is developing various alternative technologies. Among the alternative non-volatile memory technologies in the process of being developed, RRAM memories have a certain technical advantage.

RRAM memories are based on the reversible formation and rupture of a conductive filament: a dielectric material, which is normally insulating, may be forced to be conductive through a filament or a conduction path after application of a sufficiently high voltage. Once the filament is formed, it may be reset or programmed by an appropriately applied voltage.

In the particular case of OxRAM memories, the conductive filament is produced from oxygen vacancies in an insulating metal-oxide-based material. OxRAM memories benefit from a very good thermal stability, in theory making it possible to keep the information in a reliable manner for several years at high temperature, with a lifetime having a very large number of programming/deprogramming and/or read cycles.

A standard oxide used as insulating material in a memory is HfO₂. On the macroscopic scale, the zone of the oxide in which the filament is formed has either an insulating state or a conductive state in the programmed state, or a semiconductor state in the reset state.

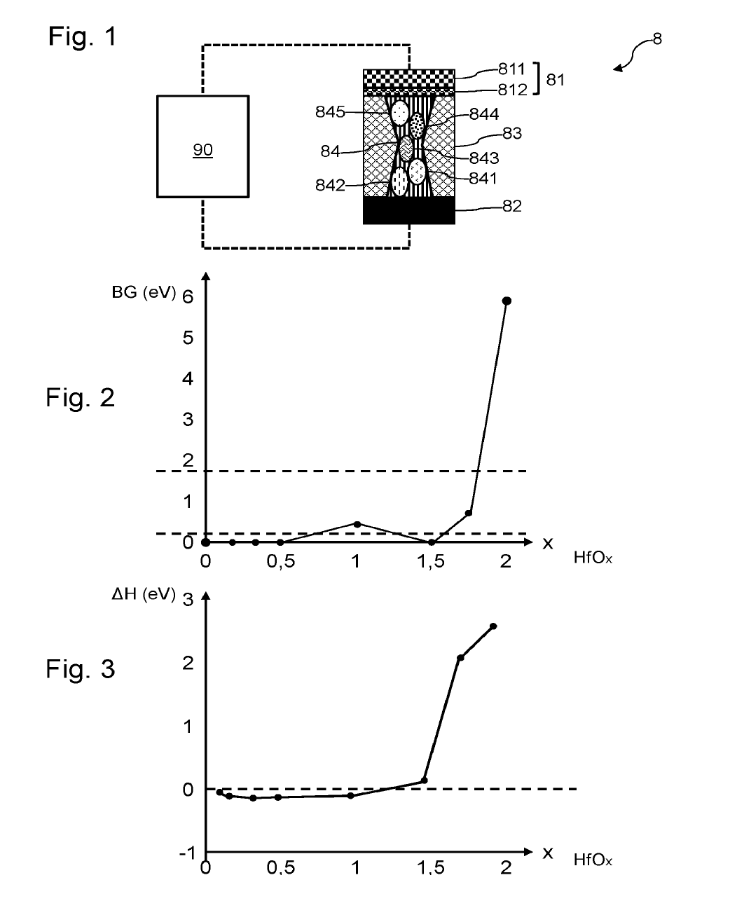

FIG. 1 is a schematic cross-sectional view of an example of an OxRAM memory location 8. The OxRAM memory location 8 comprises a metallic top electrode 81, a metallic bottom electrode 82, and a dielectric 83 inserted between the top electrode 81 and the bottom electrode 82.

The top electrode 81 is here advantageously broken down into a conductive upper element 811, and a lower element 812 for recovery of oxygen vacancies. The upper element 811 is typically made of TiN, the lower element 812 being for example made of Ti. The lower element 812 typically has a thickness of between 3 and 15 nm.

The dielectric 83 is made selectively conductive by the application of an appropriate potential difference between the top electrode 81 and the bottom electrode 82 by a control circuit 90. The dielectric 83 is intended to allow oxygen vacancies to migrate from this layer 83 to the electrode 81 or 82 in order to form the conductive filament 84 in the programmed state, and vice versa. In the programmed state, a conductive element 84 is formed in the dielectric 83. This programmed state is retained even in the absence of power supply to the memory location 8.

By applying another potential difference by means of the control circuit 90, it is possible to deprogram the memory location 8 and rupture the filament 84. The dielectric 83 has then a high resistance state, HRS.

By subsequently applying a read potential difference between the electrodes 81 and 82, the control circuit 90 can measure the current passing through the memory location 8 in order to determine whether this is in the programmed or reset state.

In practice, the dielectric 83 comprises multiple domains having different compositions in the zone of the filament 84. Thus, in the figure, zones 841 to 845 have been schematically illustrated that have various substoichiometric HfOx phases in the HfO₂.

It has been observed that these different zones 841 to 845 have different bandgap values for semiconductor oxide phases (0<BG<2). FIG. 2 shows the bandgap energy of various substoichiometric HfOx phases in the HfO₂: there are two ranges of substoichiometric phases with a metallic behaviour and a semiconductor behaviour. For the semiconductor phases, small stoichiometry variations induce variations of the bandgap. FIG. 3 shows the thermodynamic stability of the substoichiometric phases: for x<1.5, the entire range of the semiconductor phases are stable and may be formed during the change of memory state from the LRS to the HRS state. Such variations of the bandgap BG induce large dispersions in the electrical behaviour of the various memory locations, and also in the electrical behaviour of one and the same memory location for various programming/resetting cycles. Consequently, the HRS state has a large dispersion of the electrical properties which is a particularly limiting point for the industrialization of the OxRAM technology.

The invention aims to resolve one or more of these drawbacks. The invention thus relates to a method for fabricating an OxRAM memory location, as defined in the appended Claim 1.

The invention also relates to the variants of the dependent claims. A person skilled in the art will understand that each of the features of the variants of the dependent claims or of the description may be combined independently with the features of an independent claim without however constituting an intermediate generalization.

The invention also relates to an OxRAM memory location, as defined in the appended claims.

Other features and advantages of the invention will become apparent from the description which is given below, by way of indication and non-limiting, with reference to the appended drawings, in which:

FIG. 1 is a schematic cross-sectional view of a memory location according to the prior art, provided with a programming/read circuit;

FIG. 2 is a diagram illustrating the bandgap energy of various substoichiometric phases of a filament zone made in HfO₂;

FIG. 3 illustrates differences in thermodynamic stability of the various substoichiometric HfOx phases in HfO₂;

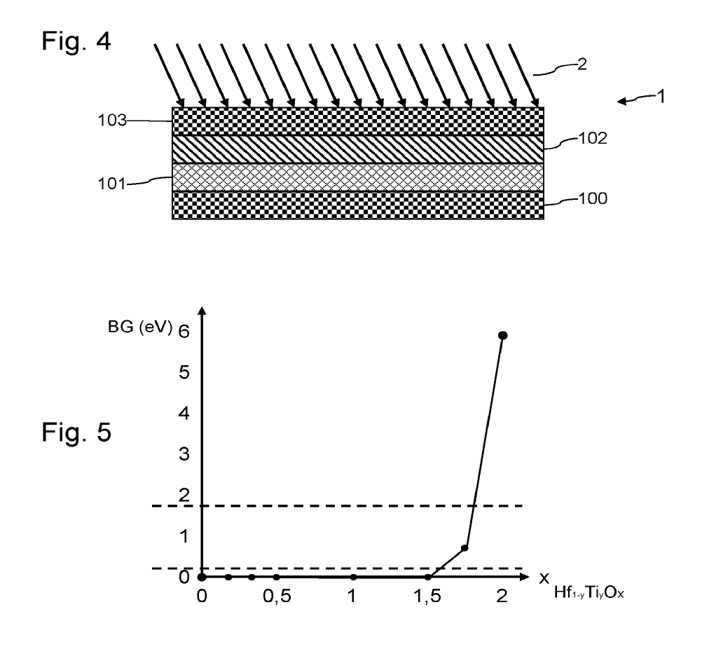

FIG. 4 is a schematic cross-sectional view of a step of a fabrication method according to an example of a first embodiment of the invention;

FIG. 5 is a diagram illustrating the bandgap energy of various substoichiometric phases of a filament zone made in an insulator produced according to the invention;

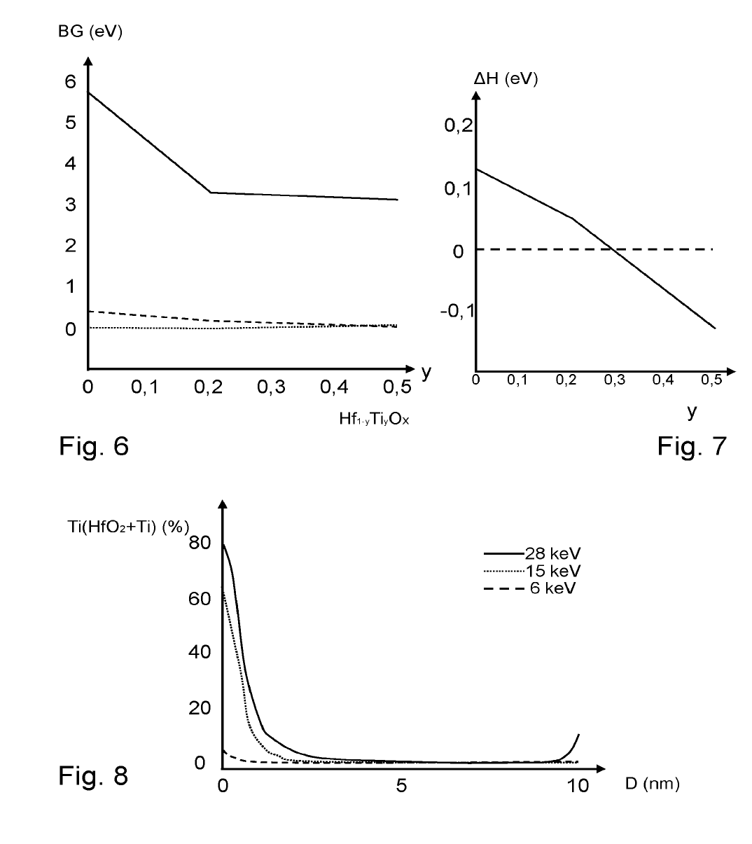

FIG. 6 is a diagram illustrating the bandgap energy of various substoichiometric phases, as a function of the proportion of titanium included;

FIG. 7 is a comparative diagram of the thermodynamic stability of a substoichiometric alloy of Hf_{1-y}Ti_{y}O_{1.5} relative to Hf_{1-y}Ti_{y}O₂, as a function of the value of y;

FIG. 8 is a diagram illustrating the proportion of titanium in a filament zone as a function of the depth, for various implantation energy values;

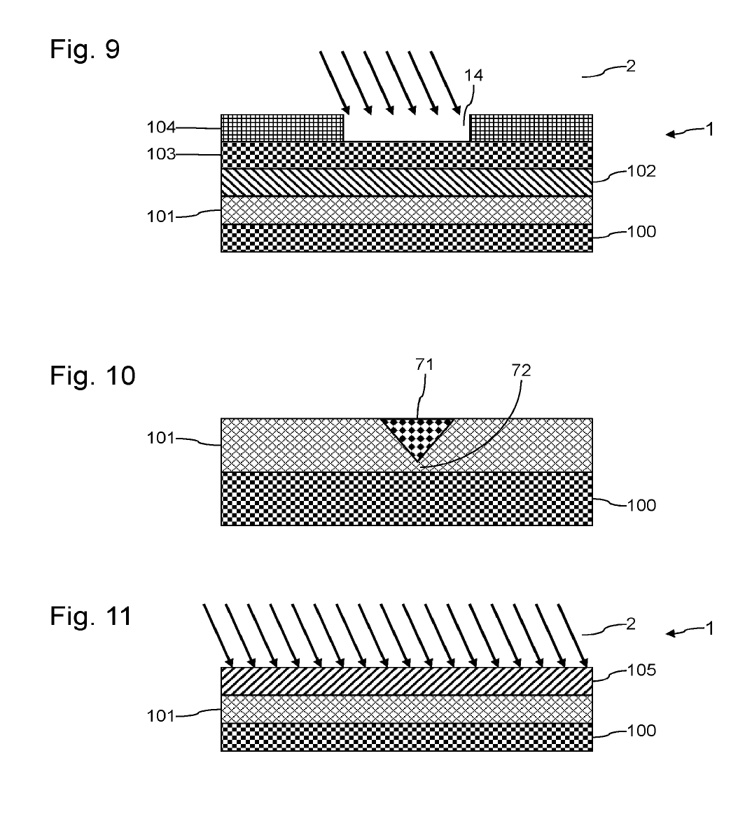

FIG. 9 is a cross-sectional view of a step of a fabrication method according to a variant of the first embodiment of the invention;

FIG. 10 is a schematic cross-sectional view of an example of the structure of a filament zone obtained by means of the method illustrated in FIG. 9;

FIG. 11 is a cross-sectional view of a step of a fabrication method according to an example of a second embodiment of the invention;

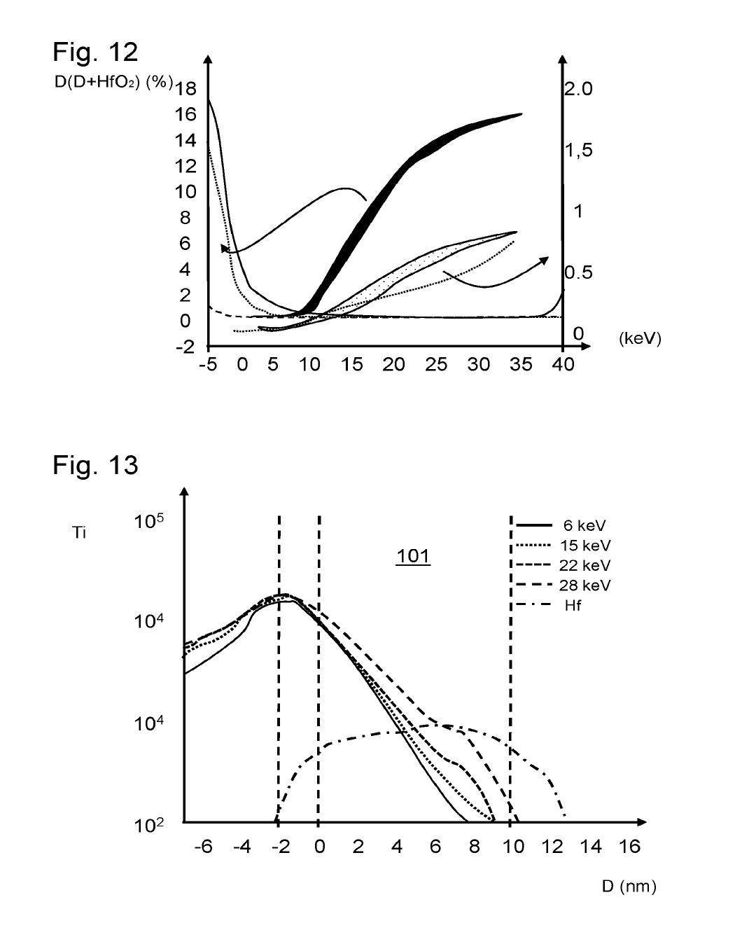

FIG. 12 is a diagram illustrating the concentration of various components in an Hf_{1-y}Ti_{y}O₂ layer, as a function of the implantation energy used for the ion implantation;

FIG. 13 is a diagram illustrating the titanium concentration as a function of the depth in a memory location, for various implantation energies.

The invention proposes a method for fabricating an OxRAM memory location. In this method, it is proposed to implant Ti in a lower HfO₂ layer. This implantation is carried out by an ion implantation of a material chosen from Xe, Kr or Ar, in an upper layer, that includes more than 50% by weight of Ti. The ion implantation in this upper layer induces therein a collision with a recoil effect, leading to an implantation of Ti in the lower HfO₂ layer.

FIG. 4 is a schematic cross-sectional view of a stack 1 during a step of a method for fabricating an OxRAM memory location, according to an example of a first embodiment of the invention.

The stack 1 here comprises the superposition of a layer 100, of a layer 101, of a layer 102 and of a layer 103. The layer 100 is for example a layer intended to form a bottom electrode of the memory location in the process of being fabricated. The layer 100 may for example be made of any appropriate conductive material, for example made of TiN in this example. The layer 103 is for example a layer intended to form a top electrode of the memory location in the process of being fabricated. The layer 103 is therefore in electrical contact with one face of the layer 101, by means of the layer 102. The layer 103 advantageously includes Ti. The layer 103 is for example made from the same material as the layer 100 and is for example formed of TiN in this example.

The layer 101 is positioned on the layer 100. The layer 101 is made of HfO₂. The layer 102 is positioned on the layer 101. The layer 102 includes a material having Ti at more than 30% by mole fraction, preferably more than 50% by mole fraction. The layer 102 is here made of Ti. The layer 103 is positioned on the layer 102. For a layer 102 made of Ti, the layer 103 advantageously makes it possible to prevent the oxidation thereof. A layer 103 made of TiN makes it possible, on the one hand, to prevent the oxidation of the layer 102 made of Ti and, on the other hand, to form an electrode for the memory location in the process of being fabricated, and furthermore to provide Ti for an implantation by collision with recoil effect in the layer 101. The layer 100 is in electrical contact with one face of the layer 101.

The method implements here a step of ion implantation of a material 2, from among Xe, Kr or Ar. The ion implantation is carried out here in the layers 103 and 102. Owing to the ion implantation in the layers 102 and 103, the collision with recoil effect on Ti of the layers 102 and 103 induces an implantation of this Ti in the layer 101. It is thus possible to form filament creation zones in the layer 101, with a composition of Hf_{1-y}Ti_{y}O₂ type.

The diagram from FIG. 5 shows the bandgap energy of various substoichiometric Hf_{1-y}Ti_{y}Oₓ phases in the Hf_{1-y}Ti_{y}O₂ of the layer 101 obtained, with a value y of 0.2. This diagram shows that the presence of these multiple substoichiometric phases with a Ti alloy makes it possible to homogenize the bandgap energies of these multiple substoichiometric phases, for x≤1.5. A single phase corresponds to a reset state, for x=1.75. Consequently, memory locations using such a dielectric have greatly reduced behaviour dispersions. Thus, the discrimination between a programmed state and a reset state may be made relatively easily. Thus, the potential differences for switching between the programmed and reset states of the memory location may be substantially reduced, without impairing the reading of the memory location.

FIG. 6 is a diagram illustrating the bandgap energy of various substoichiometric phases, as a function of the proportion of titanium included in Hf_{1-y}Ti_{y}O₂ and Hf_{1-y}Ti_{y}O_{1.5}. This diagram shows that the Hf_{1-y}Ti_{y}O₂ phase retains a high bandgap energy up to a value of y=0.5, which guarantees that good insulation properties will be retained for the Hf_{1-y}Ti_{y}O₂ phase and that the formation of semiconductor phases will be allowed. It is also observed that the Hf_{1-y}Ti_{y}Oₓ phases for x=1 or x=1.5 retain a relatively low and stable bandgap energy irrespective of the value of y.

FIG. 7 is a comparative diagram of the thermodynamic stability of a substoichiometric alloy of Hf_{1-y}Ti_{y}O_{1.5} relative to Hf_{1-y}Ti_{y}O₂, as a function of the value of y. It is observed that the Hf_{1-y}Ti_{y}O₂ is more stable than the Hf_{1-y}Ti_{y}O_{1.5}, up to a value of y of 0.3 approximately. Use will thus advantageously be made of a value y≤0.3 in order to generate less Hf_{1-y}Ti_{y}O and Hf_{1-y}Ti_{y}O_{1.5}, which are more stable and formed in a larger proportion beyond this value.

It is deduced from these diagrams that a value of y between 0.05 and 0.3 proves advantageous, for retaining both a reduction of the dispersions, an increase of the thermodynamic stability, and good insulating properties of most of the layer 101. Preferably, the value of y is between 0.1 and 0.25.

The ion implantation of Xe, Kr or Ar is carried out with an inclination of between 5° and 30° relative to the normal to the layer 102, and preferably between 7° and 25°. Such an inclination for the ion implantation makes it possible to lower the proportion of Ti in the depth of the layer 101.

FIG. 8 is a diagram illustrating the proportion of Ti in the layer 101 as a function of the depth in this layer 101, for various implantation energy values. The ion implantation is here carried out with an inclination of 7°, and an Xe ion implantation dose of 10¹⁵ cm⁻². In this example, the layer 100 was made of TiN, the layer 101 had a thickness of 10 nm, the layer 102 had a thickness of 5 nm of Ti, and the layer 103 had a thickness of 5 nm of TiN. The diagram illustrates that the concentration of Ti decreases greatly in the depth of the layer 101, which makes it possible to delimit the zone of the layer 101 that includes a significant concentration of Ti.

Furthermore, it was observed that a significant concentration of Ti was implanted in the layer 101, starting from an implantation energy at least equal to 10 keV. The implantation energy is advantageously at most 40 keV.

The implantation in the layer 101 by collision with recoil effect with Xe, Kr or Ar makes it possible to obtain relatively high concentrations of the implanted material, starting from a relatively reduced ion implantation dose, in particular with respect to a process of direct ion implantation in the layer 101. The duration of the ion implantation may thus be relatively reduced, which shortens the duration of the memory location fabrication method.

Advantageously, the ion implantation is carried out with Xe, which proves to be electrically inert and sufficiently heavy to maximize the recoil effect, which is advantageous in order not to disrupt the electrical properties of the memory location by the parasitic implantation thereof in the layer 101. Advantageously, the Xe ion implantation dose is between 2×10¹⁴ cm⁻² and 4×10¹⁵ cm⁻², preferably between 5×10¹⁴ cm⁻² and 2×10¹⁵ cm⁻².

Advantageously, the layer 103 has a thickness of between 3 and 12 nm, preferably equal to 5 nm. Preferably, the layer 102 has a thickness between 3 and 12 nm, preferably equal to 5 nm. Preferably, the sum of the thicknesses of the layers 102 and 103 is between 6 and 15 nm. Preferably, the layer 101 has a thickness of between 3 and 20 nm, preferably equal to 10 nm.

Advantageously, the ion implantation is carried out through an opening 14 of a hardmask 104, as illustrated in the cross-sectional view of FIG. 9, of a variant of the first embodiment.

FIG. 10 is a schematic cross-sectional view of an example of the structure of the layer 101, obtained by means of the variant illustrated in FIG. 9. The use of the opening 14 of the mask, combined with the decrease in the concentration of Ti in the thickness of the layer 101, makes it possible to obtain an implantation of Ti having a cross section or zone 71 of substantially triangular shape. Such cross section 71 of triangular shape makes it possible to limit the volume of the filament zone that may potentially have defects.

The cross section 71 of the layer 101 has a given proportion of Ti. The cross section 71 is surrounded here by a cross section or zone 72 of the layer 101 having a much lower proportion of Ti, or even zero Ti. In particular, the cross section 72 may have a proportion of Ti at least two times lower than that of the cross section 71.

The zone 72 forms here a separation between the zone 71 and the interface between the layers 100 and 101. Advantageously, the thickness of this separation is at least equal to 1 nm, and preferably at most equal to 2 nm (in order to guarantee a conduction across the memory location in the LRS state with a low potential difference). The presence of such a separation makes it possible to reduce the dimension of the zone 71 that may have defects, and makes it possible to obtain a point effect for the filament form, with a very precise location of the filament formed and therefore a limitation of switching dispersions.

The zone 71 may be formed by using an ion implantation with an angle of between 20° and 25° relative to the normal to the layer 101. Such an angle makes it possible to promote the point effect.

The diagram from FIG. 12 illustrates the influence of the implantation energy of the ion implantation on the concentration of various components in the layer 101. The blackened area corresponds to the concentration of Ti, the dotted area corresponds to the concentration of Xe, and the broken line corresponds to the concentration of N. It can generally be observed that the respective concentrations of N and of Xe remain relatively low irrespective of the implantation energy, and typically below 1%. It can in particular be deduced therefrom that the superposition of the layers 102 and 103 makes it possible to limit the amount of Xe implanted in the layer 101. It can also be deduced therefrom that the presence of the layer 103 does not induce an excessive concentration of N in the layer 101. A limited concentration of N in the layer 101 following the ion implantation makes it possible to avoid disrupting the switching of the memory location. It can also be observed that a high implantation energy made it possible to implant a relatively large amount of Ti in the layer 101. A memory location characteristic of a fabrication method according to the invention has a layer 101 having a concentration of Xe typically of between 0.1% and 0.9%.

According to a variant, it is possible to carry out a stepwise annealing, in a range extending from 300° C. to 450° C.: this makes it possible to make the Ti diffuse into the layer 101 and to optimize the implantation profile thereof. Such an annealing is compatible with the thermal budgets used in the metallization layers.

FIG. 11 is a cross-sectional view of a stack 1 during a step of a method for fabricating an OxRAM memory location, according to an example of a second embodiment of the invention.

The stack 1 comprises here the superposition of a layer 100 and of a layer 101, that may have the dimensions and compositions described in detail in the first embodiment. The layer 100 is here also in electrical contact with one face of the layer 101.

The stack 1 further comprises a TiO₂ layer 105. The layer 105 is positioned on the layer 101. The layer 105 has a thickness of between 3 and 12 nm, preferably equal to 5 nm. In this embodiment, the TiO₂ layer 105 may be obtained by previously carrying out the deposition of Ti on the layer 101, then by letting this layer of Ti oxidize in order to form the TiO₂ layer 105.

The method here also carries out a step of ion implantation of a material 2, from among Xe, Kr or Ar. The ion implantation is carried out here in the layer 105. Owing to the ion implantation in the layer 105, the collision with recoil effect on Ti of the layer 105 induces an implantation of this Ti in the layer 101. It is thus possible to form filament creation zones in the layer 101, with a composition of Hf_{1-y}Ti_{y}O₂ type. The ion implantation may be carried out with the same inclination, dose or implantation energy parameters.

The ion implantation is carried out with a layer 105 that is bare and directly in contact with the layer 101. Thus, for a given implantation energy, the proportion of Ti that can be implanted in the layer 101 by collision with recoil effect may be increased. Furthermore, owing to the density of oxygen in the layer 105, the implantation by collision with rebound effect promotes the formation of the Hf_{1-y}Ti_{y}O₂ phase in the layer 101. It is thus possible to better control the switching between the programmed state and the reset state of the memory location.

The fabrication method may comprise a subsequent step of depositing a layer of TiN on the layer 105, with a view to forming another electrode of the memory location.

The diagram from FIG. 13 represents the concentration of Ti as a function of the depth, in a stack 1, for various Xe implantation energies. The depth D=0 corresponds to the interface between a layer 102 as described previously and a layer 101 having a thickness of 10 nm. The solid line curve corresponds to an Xe implantation energy of 6 keV, the dotted line curve corresponds to an Xe implantation energy of 15 keV, the broken line curve corresponds to an Xe implantation energy of 22 keV, another broken line curve corresponds to an Xe implantation energy of 28 keV, and the dot-and-dash line curve corresponds to the plot of the Hf.

It can be observed, on the one hand, that the decrease in the proportion of Ti in the layer 101 decreases relatively linearly, irrespective of the implantation energy. Such an implantation can therefore quite easily enable a Ti implantation profile having a cross section or zone 71 of substantially triangular shape to be obtained, as illustrated in FIG. 10. Furthermore, it can be observed that the implantation energy makes it possible to influence quite precisely the concentration of Ti at the interface between the layers 101 and 102, as a function of the Xe implantation energy. It is furthermore observed that the implantation energy makes it possible to control quite precisely the Ti implantation depth, and therefore to control quite precisely the dimension of a thickness of a zone 72 between the cross section 71 and the interface between the layers 100 and 101.

1. The method for fabricating an OxRAM memory location, comprising the steps of:
providing a stack comprising a superposition of:
a first layer that includes a first material made of Ti at more than 30% by mole fraction;
a second layer made of HfO₂ positioned under the first layer;
via an ion implantation of a second material chosen from Xe, Kr or Ar in the first layer, said implantation being carried out with an inclination of between 5° and 30° relative to the normal to the first layer, carrying out an implantation of the first material in the second layer by collision with recoil effect in the first layer.

2. A fabrication method according to claim 1, wherein said first material is Ti, and wherein said implantation of the first material in the second layer is carried out in a first zone, so that the composition in said first zone is Hf_{1-y}Ti_{y}O₂, with y between 0.05 and 0.3.

3. The fabrication method according to claim 2, wherein said second layer comprises a second zone surrounding the first zone, wherein second zone the proportion of Ti is at least two times lower than that of the first zone.

4. The fabrication method according to claim 3, wherein said second layer is positioned on a third layer made of a material different from that of the second layer, said second zone separating the first zone from an interface between the second layer and the third layer.

5. The fabrication method according to claim 4, wherein the thickness of the second zone separating the first zone from an interface between the second layer and the third layer is at least equal to 1 nm.

6. The fabrication method according to claim 2, wherein said stack provided comprises a fourth layer, positioned on the first layer, the fourth layer being made of TiN, the first layer being made of Ti.

7. The fabrication method according to claim 2, wherein said first layer is made of TiO₂.

8. The fabrication method according to claim 1, wherein said step of ion implantation of the second material is carried out with an implantation energy of between 10 and 40 keV.

9. The fabrication method according to claim 1, wherein said second material is Xe and wherein said ion implantation dose is between 2×10¹⁴ cm⁻² and 4×10¹⁵ cm⁻².

10. The fabrication method according to claim 1, wherein said stack provided comprises a first layer having a thickness of between 3 and 12 nm, and a second layer having a thickness of between 7 and 20 nm.

11. The fabrication method according to claim 1, comprising the formation of first and second electrodes in electrical contact respectively with an upper face and with a lower face of said second layer.

12. The fabrication method according to claim 11, comprising a step of connecting a programming/resetting circuit to the first and second electrodes, said programming/resetting circuit being configured in order to selectively apply a potential difference between the first and second electrodes so as to create/rupture a conductive filament across the second layer.

13. The fabrication method according to claim 1, wherein said stack provided comprises a hardmask comprising an opening, said ion implantation being carried out through said opening.

14. An OxRAM memory location, comprising a stack comprising a superposition of:
a first layer that includes a first material made of Ti at more than 30% by mole fraction;
a second layer that predominantly includes HfO₂, positioned under the first layer and having an implantation of Ti;
wherein the second layer includes Xe with a molar concentration of between 0.1% and 0.9%.
